(19) United States
(12) Patent Application Publication
(10) Pub. No.: US 2019/0334448 A1
(43) Pub. Date: Oct. 31, 2019

(54) INVERTER CONTROL DEVICE

(71) Applicants: Nidec Corporation, Kyoto (JP); Nidec Elesys Corporation, Kawasaki-shi (JP)

(72) Inventors: Yuki ISHIKAWA, Kyoto (JP); Naoki IWAGAMI, Kawasaki-shi (JP); Hitoshi KUROYANAGI, Kawasaki-shi (JP)

(21) Appl. No.: 16/394,425

(22) Filed: Apr. 25, 2019

(30) Foreign Application Priority Data
Apr. 25, 2018 (JP) 2018-084582

(51) Int. Cl. H02M 7/00; H02K 11/33; H02M 7/5387; H05K 5/04; H05K 7/20; H01L 23/473

(52) U.S. Cl. CPC H02M 7/003; H02K 11/33; H02M 7/53871; H02P 27/08; H05K 7/20927; H01L 23/473; H05K 7/20872; H05K 5/04

(57) ABSTRACT

An inverter control device includes a flow path through which a cooling refrigerant flows is defined in a bottom surface of a casing made of a metal material. The flow path includes a flow inlet and a flow outlet in a first side surface of the casing, and includes an outward path that extends to a second side surface opposite to the first side surface from the first side surface, and a return path that extends to the first side surface from the second side surface.

### CROSS REFERENCE TO RELATED APPLICATION

The present invention claims priority under 35 U.S.C. § 119 to Japanese Application No. 2018-084582 filed on Apr. 25, 2018 the entire contents of which is incorporated herein by reference.

### 1. FIELD OF THE INVENTION

The present disclosure relates to a structure of an inverter control device that is an in-vehicle power conversion device.

### 2. BACKGROUND

Electric cars, hybrid cars, and the like in which an electric motor is a driving source have been becoming popular as environmentally friendly vehicles in recent years. In those electric cars and the like, an inverter device (power conversion device) that accelerates and decelerates a vehicle by converting DC power from a battery to AC power to be supplied to a driving motor and controlling a motor rotation speed, a driving torque, and the like is installed.

As with other electronic devices, also in the in-vehicle inverter device, electronic parts mounted on a circuit board are becoming highly integrated, and the amount of heat generated by the electronic parts is increasing in accordance with the increase in output for a further acceleration performance. In the related art, there is a flow path configuration that cools parts used in an in-vehicle power conversion device. In the related art, first to third flow paths are included around a capacitor module, the second flow path and the third flow path are arranged so as to be opposite to each other, and power modules forming upper and lower arms for supplying each phase current of a three-phase AC are each arranged in each flow path of the first to the third flow paths.

In the inverter device (power conversion device), the temperature of the board rises by the heat from the power modules from a bridge circuit and the like using power elements that generate a particularly large amount of heat, and the temperature of an adjacent capacitor and the like also rises due to the influence thereof. In the power conversion device of the related art, a squared U-shaped flow path is formed so that cold water flows along three side surfaces of flow-path forming bodies in order to not only cool the power modules but also collectively cool other parts used in the power conversion device.

That is, the flow path is provided along the side surfaces of a casing forming the flow path in order to cool the other parts included in the power conversion device of the related art as well. As a result, even when the power modules are arranged along the flow path, there has been a problem in that a high heat dissipation efficiency cannot be obtained for elements that generate a large amount of heat in the inverter device, and the heat dissipation effect is low.

Further, in the related art, a three-phase AC interface and an inlet and an outlet of piping for a cooling medium are arranged on the same side surface of a housing. Therefore, a wiring cord for electricity and a hose for supplying the refrigerant are mixed together and concentrated on the same surface of the housing, thereby causing the work efficiency of the wiring and the piping to decrease.

### SUMMARY

Example embodiments of the present invention are able to solve the abovementioned problem. That is, a first example embodiment of the present invention provides an inverter control device in which a flow path through which a cooling refrigerant flows is defined in a bottom surface portion of a casing made of a metal material. The flow path includes a flow inlet and a flow outlet in a first side surface of the casing. The flow path includes an outward path that extends to a second side surface opposite to the first side surface from the first side surface, and a return path that extends to the first side surface from the second side surface.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic configuration of a vehicle in which an inverter control device according to an example embodiment of the present disclosure is installed.

FIG. 2 is an external view of the inverter control device in which a driving motor and a gear are combined and integrated.

FIG. 3 is an external view of the inverter control device according to this example embodiment seen from one side-surface side.

FIG. 4 is an external view of the inverter control device seen from a bottom surface side.

FIG. 5A is a perspective view partially illustrating only a bottom portion by removing a casing upper portion of the inverter control device.

FIG. 5B is a cross-sectional view of an outward path and a return path when the casing is taken along arrow line X-X′ and arrow line Y-Y′ in FIG. 5A.

### DETAILED DESCRIPTION

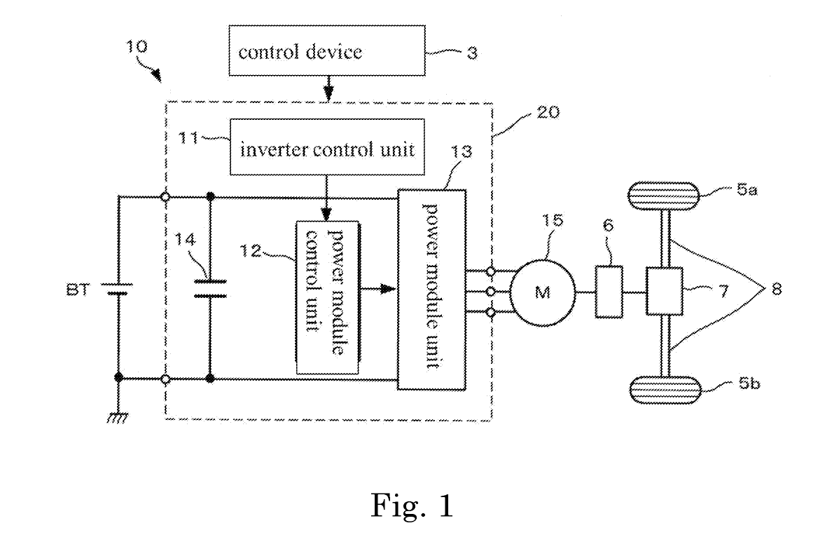

Example embodiments according to the present disclosure is described below in detail with reference to the accompanying drawings. FIG. 1 is a schematic configuration of a vehicle in which an inverter control device according to an example embodiment of the present disclosure is installed. In FIG. 1, an electric motor 15 is a three-phase AC motor, for example, and is a driving force source of the vehicle. A rotation shaft of the electric motor 15 is connected to a reducer 6 and a differential gear 7, and a driving force (torque) of the electric motor 15 is transmitted to a pair of wheels 5a and 5b via the reducer 6, the differential gear 7, and a drive shaft (driving shaft) 8.

An inverter unit 20 of an inverter control device 10 includes a power module unit 13 that supplies driving power to the electric motor 15, a power module control unit 12 that outputs a driving signal to the power module unit 13, an inverter control unit 11 that outputs a control signal to the power module control unit 12, and a smoothing capacitor 14. The inverter unit 20 is controlled by a control signal from a control device 3 that is responsible for the control of the entire vehicle.

The power module unit 13 includes a bridge circuit (power conversion circuit) obtained by connecting two power switching elements (an upper-arm power switching element and a lower-arm power switching element) such as Insulated Gate Bipolar Transistors (IGBTs) and Metal Oxide Semiconductor Field Effect Transistors (MOSFETs) for each of a U-phase, a V-phase, and a W-phase, that is, a total of six power switching elements.

The power module unit 13 converts DC power from a battery BT to AC power (three-phase AC power) by switching the ON/OFF of the power switching elements by a driving signal (PWM control signal) from the power module control unit 12, and drives the electric motor 15 by the conversion.

The battery (BT) is a supply source of electrical energy that is a power source of the vehicle, and is formed by a plurality of secondary batteries, for example. The capacitor 14 is arranged in the inverter unit 20 at a part connected to the battery (BT). The capacitor 14 is connected between a high-potential line (positive-electrode potential B+) and a low-potential line (negative-electrode potential B-(GND)), and is a high-capacity smoothing capacitor (film capacitor) that smooths the input voltage from the battery BT.

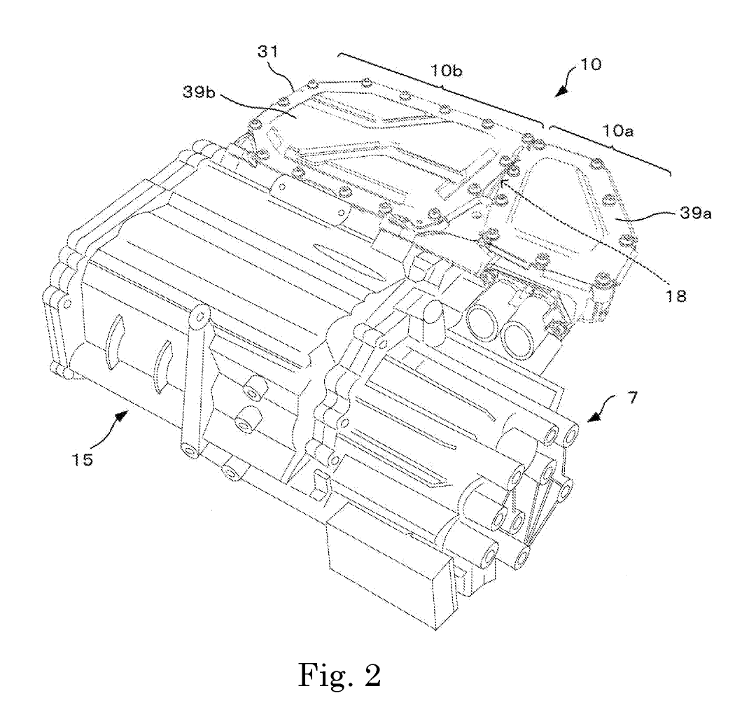

The structure of the inverter control device according to this example embodiment is described. FIG. 2 is an external view of the inverter control device 10, and illustrates a state in which the inverter control device 10, the electric motor 15, and the gear 7 are combined and integrated. A casing 31 of the inverter control device 10 is obtained by molding an aluminum die casting, for example. The inverter control device 10 includes a high-voltage circuitry 10a that is an input unit for high-voltage current from an external battery (the battery (BT) in FIG. 1), and a power controller 10b that supplies driving current to a driving motor.

The high-voltage circuitry 10a and the power controller 10b are separated from each other via a partition wall 18 in the casing 31. Upper surface portions of the high-voltage circuitry 10a and the power controller 10b are covered with covers 39a and 39b that are flat-plate-like members made of metal such as aluminum, for example.

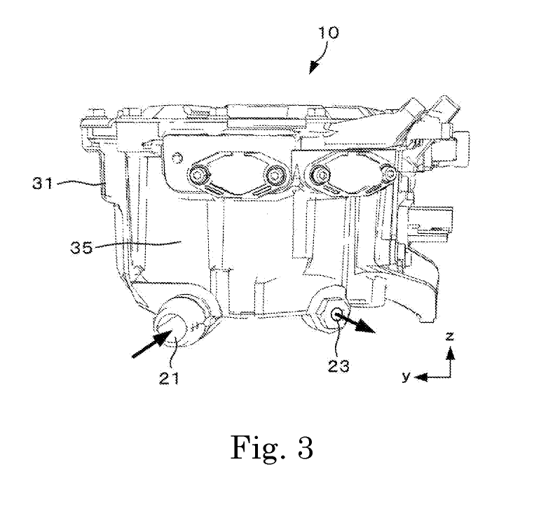

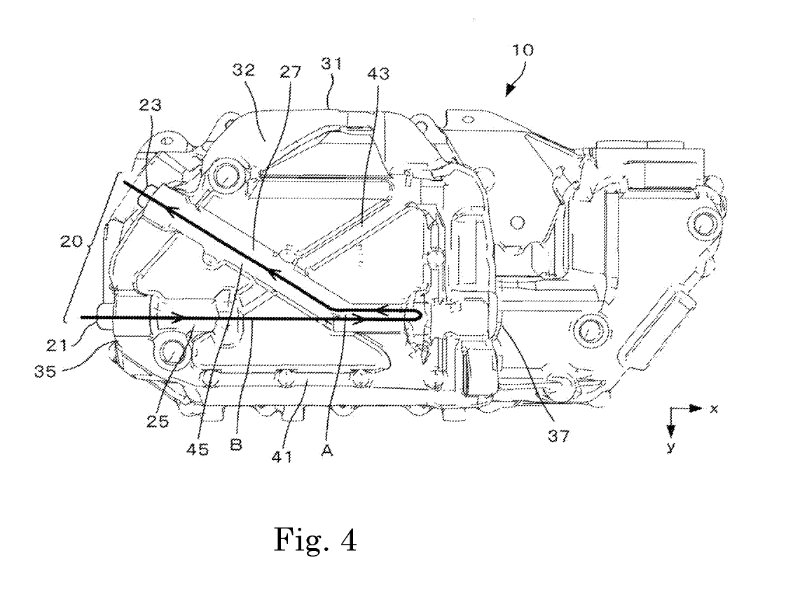

Next, a flow path structure of the inverter control device according to this example embodiment is described. FIG. 3 is an external view of the inverter control device 10 according to this example embodiment seen from one side-surface side, and FIG. 4 is an external view of the inverter control device 10 seen from the bottom surface side.

As illustrated in FIG. 4, a flow path 20 through which a cooling refrigerant such as cooling water and cooling liquid flows is formed in a bottom surface portion 32 of the casing 31 of the inverter control device 10. The flow path 20 is integrally formed with the casing 31 in the bottom surface portion 32, and is a pipe-shaped passage with a circular cross-sectional shape. By creating the cross section to be circular, the pressure loss of the cooling refrigerant in the flow path can be suppressed. For example, the diameter of the flow path is made to be about 11 millimeters in order to have the cooling refrigerant flow by 8 liters per minute and keep the pressure loss in the flow path at 5 kilopascals or less.

The flow path 20 includes an outward path 25 and a return path 27. As illustrated in FIG. 3 and FIG. 4, the outward path 25 is a flow path having a flow inlet 21 of the cooling refrigerant in one side surface (first side surface) 35 of the casing 31 and reaching another side surface (second side surface) 37 opposite to the one side surface 35 from the one side surface 35. The outward path 25 extends in a substantially linear manner to the other side surface 37 from the one side surface 35 in the bottom surface portion 32 of the casing 31.

The return path 27 is a flow path that reaches the one side surface (first side surface) 35 from the other side surface (second side surface) 37 of the casing 31, and has a flow outlet 23 of the cooling refrigerant in the one side surface 35 of the casing 31 as with the flow inlet 21 of the outward path 25. The return path 27 extends along a diagonal line on the bottom surface portion 32 of the casing 31. The flow path 20 is in a sealed state besides the flow inlet 21 and the flow outlet 23.

Note that the drilling for creating the flow paths of the outward path 25 and the return path 27 in the casing becomes easier by making the outward path 25 and the return path 27 in a linear fashion without bending.

As illustrated in FIG. 4, the outward path 25 and the return path 27 intersect with each other at an approximately central portion A of the bottom surface portion 32 of the casing 31. In the small-sized inverter control device 10, such an intersection of the outward path 25 and the return path 27 enables the total length of the flow path 20 to be longer in the bottom surface portion 32 of the casing of which an area is limited, and thus the heat dissipation efficiency can be improved. Therefore, the cooling refrigerant of the inverter control device 10 flows into a route B indicated by a bold line in FIG. 4, that is, flows from the flow inlet 21 of the outward path 25 on the upstream side of the refrigerant flow path, turns around at a terminal portion of the outward path 25, flows through the return path 27, and then flows out from the flow outlet 23 on the downstream side.

In addition, in the bottom surface portion 32 of the casing 31 of the inverter control device 10, a rib 41 is formed so as to surround the periphery of the bottom surface portion 32 in order to increase mechanical strength. Further, two ribs 43 and 45 are formed along respective diagonal lines on the bottom surface portion 32. The rib 45 is composed of a protrusion of the return path 27 to the outside of the bottom surface at the bottom surface portion 32, and the inside of the rib 45 is the flow path (return path 27) of the cooling refrigerant.

As described above, the rib 45 extending along the diagonal line serves as both of a flow path of the refrigerant and a reinforcement member for the mechanical strength of the bottom surface portion 32 of the casing, and hence a rib for reinforcement does not necessarily need to be provided separately, which can reduce the cost of the casing.

In addition, the casing 31 may largely vibrate when the electric motor is driven. Noise may be generated by the vibration of the casing 31, and the noise may be transmitted to a passenger seat of the vehicle. The noise may cause discomfort for a person in the passenger seat in some cases. As measures against the vibration, the ribs 41, 43, and 45 are formed in the casing 31. By the ribs 41, 43, and 45, the vibration of the casing 31 can be suppressed. In particular, the rib 45 serves as both of the flow path of the refrigerant and the measures against the vibration of the casing 31. Accordingly, there is no need to provide another rib for the measures against vibration, and the vibration of the casing 31 can be suppressed by the minimum number of ribs.

Note that the rib 45 serving as the measures against vibration should extend from the one side surface 35 to a side surface (third side surface) other than the other side surface 37 of the casing on the bottom surface portion 32 of the casing 31. That is, the rib 45 should extend from the one side surface 35 to a side surface (the second side surface, the third side surface) different from the one side surface 35 of the casing 31 on the bottom surface portion 32 of the casing 31. In addition, a case where only a part of the rib 45 is the flow path of the refrigerant in the direction in which the rib 45 extends is possible. That is, the rib 45 that does not include the flow path of the refrigerant may extend on a line extending from the flow path of the refrigerant. Further, the rib 45 may extend from the one side surface 35 to the other side surface 37 of the casing in a substantially linear manner, or may extend along a diagonal line on the bottom surface portion 32 of the casing 31.

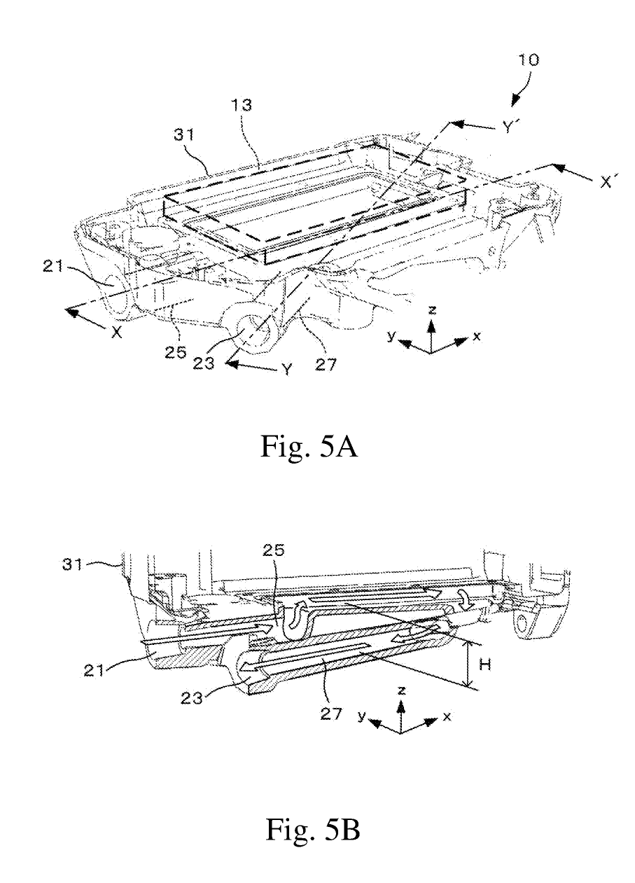

The structure of the flow path of the inverter control device is described in detail below. FIG. 5A is a perspective view partially illustrating only the bottom portion by removing the upper portion of the casing 31 of the inverter control device 10. In the inverter control device 10, a cooling object (member to be cooled) by the cooling refrigerant flowing through the abovementioned flow path 20 is mainly a power module unit 13 (illustrated by a dotted line in FIG. 5A) accommodated in the casing 31.

The power module unit 13 is arranged in a position in the bottom portion in the casing 31 that is directly above the outward path 25 and corresponding to the approximately central portion A of the bottom surface portion 32 illustrated in FIG. 4. The power module unit 13 is composed of a bridge circuit and the like including a plurality of power elements that generate a large amount of heat. Therefore, dissipation of heat (removal of heat) from the power elements is achieved through contact of the power module unit 13 with the cooling refrigerant at the abovementioned position.

FIG. 5B is a cross-sectional view illustrating a detailed structure of the flow paths (the outward path 25 and the return path 27) in the inverter control device 10 when the casing 31 is taken along arrow line X-X′ and arrow line Y-Y′ in FIG. 5A in the vertical direction. The outlined arrows in FIG. 5B indicate the flow of the cooling refrigerant in the outward path 25 and the return path 27.

The cooling refrigerant injected from the flow inlet 21 flows through the outward path 25 that is on the upstream side of the refrigerant flow path, and the heat generated by the power module unit 13 arranged directly above the outward path 25 is transmitted to the cooling refrigerant as described above during the flow. Then, the cooling refrigerant flows out from the flow outlet 23 via the return path 27 that is on the downstream side of the refrigerant flow path.

Now, when a positional relationship between the outward path 25 on the upstream side and the return path 27 on the downstream side is focused on, a height difference H is provided between the outward path 25 and the return path 27 in the height direction (z-axis direction) of the casing 31 as illustrated in FIG. 5B. By arranging the outward path 25 at a position that is higher than the return path 27 as described above, the cooling refrigerant can flow in from a high position and smoothly flow toward a low position and can be efficiently taken out from the flow outlet 23. As a result, the flow of the cooling refrigerant in the flow route (flow path 20) can be facilitated.

As described above, in the inverter control device according to this example embodiment, the flow inlet and the flow outlet of the cooling refrigerant are arranged on one side surface of the casing, and the outward path extending in a substantially linear manner through the bottom surface portion from the one side surface to the other side surface opposite thereto and the return path extending along the diagonal line on the bottom surface portion toward the one side surface from the other side surface are formed. Further, the outward path and the return path are configured to intersect with each other at the approximately central portion of the bottom surface portion of the casing.

With the flow path structure as above, the cooling refrigerant turns around at the terminal portion of the outward path and flows through the return path, and hence the total length of the flow path can be longer in the bottom surface portion of the casing of which an area is limited. As a result, heat can be efficiently removed from the power module unit that is arranged at the approximately central portion of the bottom surface portion generating a large amount of heat, and thus the heat dissipation efficiency can be improved.

In addition, heat from not only the power module unit but other heat generating parts can be dissipated to the outside of the casing in a more efficient manner, and the temperature rise of the entire inverter control device can be reduced.

Further, by arranging the inlet and the outlet of the flow path on one side-surface side of the casing, the routing of a hose for supplying the refrigerant in an installation space in the inverter control device in the vehicle becomes easier and the necessary hose length can be reduced.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An inverter control device, comprising:
a casing made of metal and including a bottom surface; and
a flow path through which a cooling refrigerant flows defined in the bottom surface of the casing; wherein
the flow path includes a flow inlet and a flow outlet in a first side surface of the casing, and includes an outward path that extends to a second side surface opposite to the first side surface from the first side surface, and a return path that extends to the first side surface from the second side surface.

2. The inverter control device according to claim 1, wherein the outward path and the return path intersect with each other at the bottom surface of the casing.

3. The inverter control device according to claim 2, wherein the outward path extends in a linear or substantially linear manner to the second side surface from the first side surface and the return path extends along a diagonal line on the bottom surface.

4. The inverter control device according to claim 3, further comprising:
a pair of ribs that extend along respective diagonal lines on the bottom surface and intersect with each other, wherein
a flow path through which the cooling refrigerant flows is defined in at least one rib of the pair of ribs.

5. The inverter control device according to claim 1, wherein the outward path is located in an upper portion relative to the return path in a height direction of the casing.

6. The inverter control device according to claim 1, wherein a member to be cooled is brought into contact with the cooling refrigerant at a central or substantially central portion of the outward path.

7. The inverter control device according to claim 6, wherein the member to be cooled is a power module including a plurality of power semiconductor devices and supplies a driving current to a motor.

8. The inverter control device according to claim 1, wherein the flow path has a circular cross-sectional shape with a predetermined diameter.

9. The inverter control device according to claim 1, wherein the casing and the flow path are integrally provided in the bottom surface of the casing.
